(19) United States
(12) Patent Application Publication
(10) Pub. No.: US 2013/0120939 A1
(43) Pub. Date: May 16, 2013

(54) METHOD AND DEVICE FOR THERMALLY COUPLING A HEAT SINK TO A COMPONENT

(71) Applicants: Stefan Voss, Ratingen (DE); Andreas Siebert, Koln (DE)

(72) Inventors: Stefan Voss, Ratingen (DE); Andreas Siebert, Koln (DE)

(73) Assignee: NOKIA SIEMENS NETWORKS OY, ESPOO (FI)

(21) Appl. No.: 13/699,366

(22) PCT Filed: May 21, 2010
(86) PCT No.: PCT/EP10/57039

§ 371 Date: Jan. 18, 2013

(51) Int. Cl. F28F 9/00; H05K 7/20; H05K 13/04

(52) U.S. Cl. CPC F28F 9/00; H05K 13/04; H05K 7/20409
USPC 361/710; 156/295

(57) ABSTRACT

A heat sink is thermally coupled to a component with a thermal filler and an intermediate layer applied between the heat sink and the component. The intermediate layer is formed with apertures and the heat sink is pressed against the component with a given force in order for the thermal filler to penetrate the apertures of the intermediate layer.

The invention relates to a method and to a device for thermally coupling a heat sink to a component.

Today, some electrical components are consuming a considerable amount of power, which dissipates as heat. Therefore components heat up and heat sinks are used to dissipate heat from these electrical components in order to avoid damages and to extend a durability of the electrical components.

In some applications, thermal resistance between the heat sink and a component is high (even if the heat sink can be directly attached to the electrical component) due to mechanical constrains and/or tolerances and/or a gap between the heat sink and the component. In such scenarios, a thermal filler (e.g., thermal conductive gel, paste or liquid) is applied between the electrical component and the heat sink. The thermal filler provides good thermal conductivity and may vary in thickness due to particular mechanical requirements.

During a product lifecycle, the heat sink may have to be separated from the electrical component, e.g., in case the electrical component needs to be replaced or for repair purposes within a hardware module comprising such heat sink. The thermal filler, however, is cohesive and a significant amount of force is required for separating the heat sink from the electrical component. The printed circuit boards and/or electrical components are susceptible to such mechanical force being applied and may be damaged during the separation process.

This is in particular a significant problem in case a housing is used as heat sink for several components attached to one or more printed circuit board. In such scenario, a considerable amount of force is required to separate the housing (or a part thereof) from the components, because of the multiple spots where the housing is glued to the components via the thermal filler.

It is a further disadvantage that larger portions of the thermal filler remain on the electrical component after it has been separated from the heat sink. As a result, the electrical component and the printed circuit board need to be cleaned to remove the old thermal filler before new thermal filler can be applied and the component(s) can be re-connected with the heat sink.

The problem to be solved is to avoid the above mentioned disadvantages and in particular to provide an efficient solution that allows separating the heat sink from the electrical component without damaging the electrical component or the printed circuit board to which the electrical component is attached.

This problem is solved according to the features of the independent claims. Further embodiments result from the depending claims.

In order to overcome this problem, a method is provided for thermally coupling a heat sink to a component, in particular an electrical component,
wherein a thermal filler and an intermediate layer are applied between the heat sink and the component.

Advantageously, the separation between the heat sink and the (electrical) component is facilitated via said intermediate layer. Hence, damages to the component can be avoided in case the heat sink and the component are separated.

In an embodiment, the component is an electrical component, in particular an integrated circuit that is in particular mounted or attached to a socket on a printed circuit board.

The electrical component may be any integrated circuit, e.g., a microcontroller, processor, memory devices, ASIC, FPGA, transistor, or the like. It may also refer to any electrical component exposed to high currents, which requires cooling, e.g., a power controller or any high current-carrying component.

It is noted that the component may be electrically connected to the printed circuit board via a socket or it may be directly mounted (soldered) on the board.

In another embodiment, the heat sink is part of a housing or thermally coupled with at least a part of the housing.

A housing could be provided comprising a protrusion that presses against the intermediate layer or the thermal filler. The housing may comprise active or passive cooling means for dissipating heat from the electrical component.

In a further embodiment, the intermediate layer comprises at least one of the following:
a gauze;
a fiberglass structure;
a ceramic structure;
a foil;
a meshed structure;
a texture;
a textile.

In a next embodiment, the intermediate layer is pre-processed with a primer in particular to improve a contact with the thermal filler

It is also an embodiment that the intermediate layer comprises a porosity.

The intermediate layer may in particular comprise apertures or holes of (substantially) the same or of different size and/or form. The porosity could be provided such that the heat sink has to be pressed against the (electrical) component with a given force in order for the thermal filler to penetrate the holes of the intermediate layer.

Pursuant to another embodiment, the heat sink is pressed against or towards the component.

The heat sink may be pressed against the components for a given duration and/or with a given force.

According to an embodiment, the thermal filler is applied on the heat sink.

According to another embodiment, the thermal filler is applied on the component.

In yet another embodiment, the thermal filler is applied on at least one side of the intermediate layer.

According to a next embodiment, the thermal filler comprises at least one of the following:
a thermal conductive gel;
a thermal conductive paste;
a thermal conductive liquid.

The problem stated above is also solved by a device comprising
a heat sink;
a component;
wherein the heat sink and the component are connected via an intermediate layer and at least one thermal filler.

Pursuant to an embodiment, the heat sink is part of a housing.

According to another embodiment, the thermal filler is arranged on both sides of the intermediate layer.

According to a further embodiment, the intermediate layer is larger than the component or the intermediate layer extends (at least partially) beyond the edge of the component.

Hence, it can be avoided that the thermal filler is pressed beyond the intermediate layer and contaminates the printed circuit board.

In a next embodiment, the device is a component of a communication system.

Embodiments of the invention are shown and illustrated in the following figures:

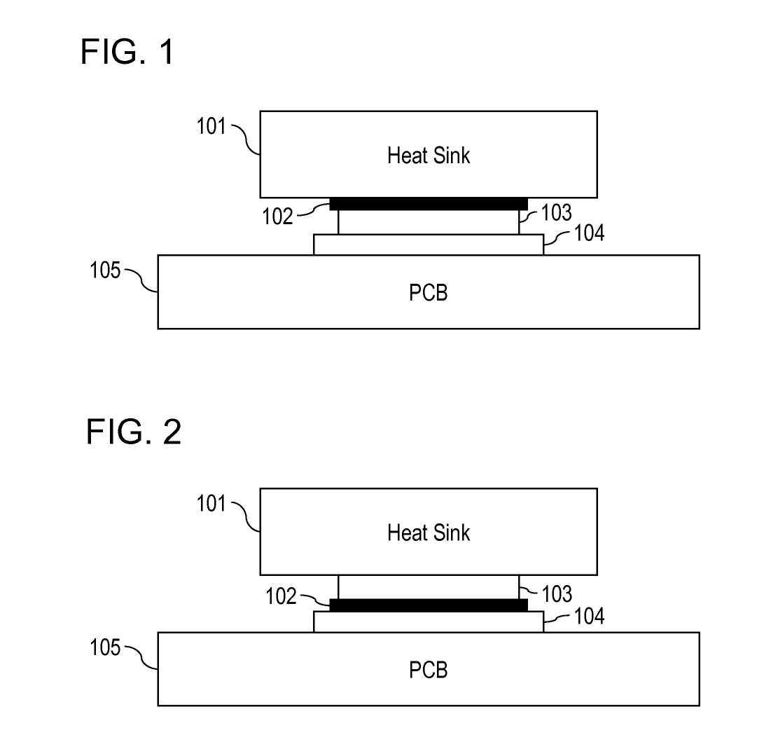

FIG. 1 shows a schematic comprising an electrical component that is mounted on a printed circuit board (PCB) with a thermal filler applied on top of the electrical component and an intermediate layer arranged on top of the thermal filler;

FIG. 2 shows a schematic comprising an electrical component that is mounted on a printed circuit board (PCB) with the thermal filler applied on top of the heat sink and the intermediate layer arranged on top of the thermal filler;

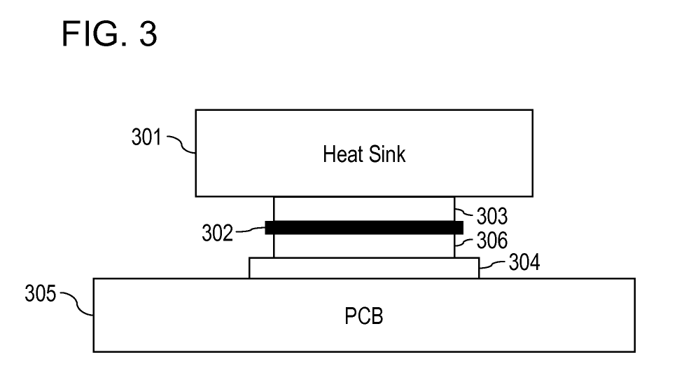

FIG. 3 shows a schematic with a heat sink that is thermally coupled with an electrical component that is mounted on a PCB, wherein such thermal coupling is provided by an intermediate layer connected via a thermal filler with the heat sink and via a thermal filler with the electrical component;

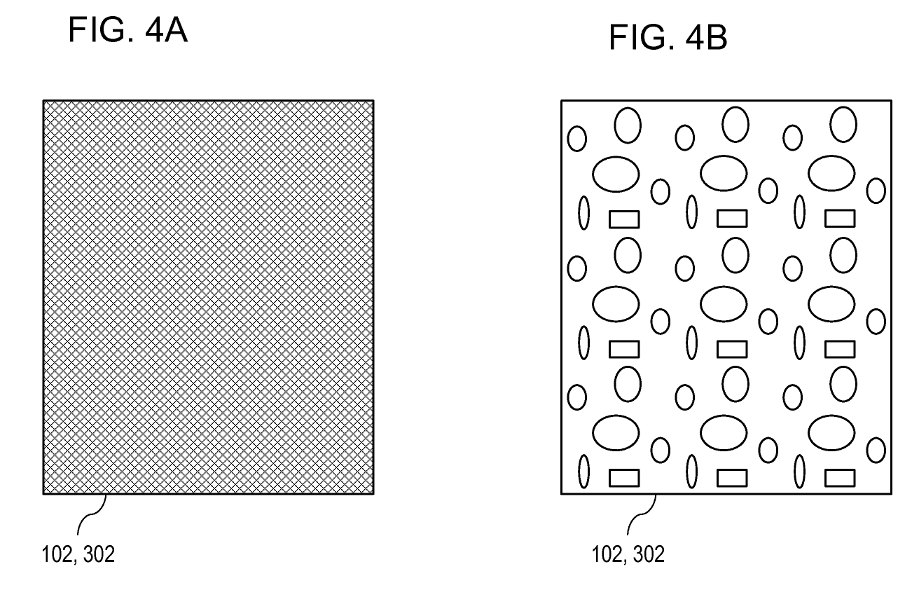

FIG. 4A shows an exemplary structure of an intermediate layer comprising a meshed structure with a given porosity;

FIG. 4B shows an alternative exemplary structure of an intermediate layer comprising various holes of different form and diameter;

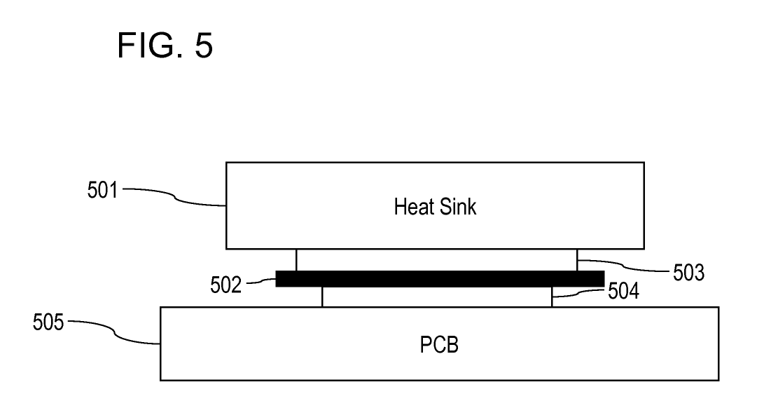

FIG. 5 shows a schematic comprising an electrical component that is mounted on a PCB with the thermal filler applied on top of the heat sink and the intermediate layer arranged on top of the thermal filler, wherein the intermediate layer is larger in size than the electrical component's surface;

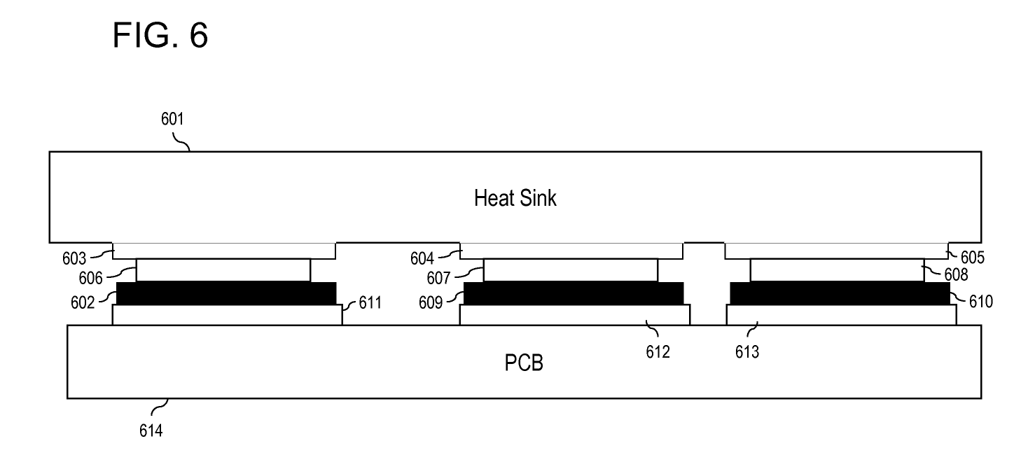

FIG. 6 shows a housing, which is used as a heat sink comprising several protrusions, wherein each protrusion is thermally coupled via a thermal filler and an intermediate layer to an electrical component, which is attached to a PCB.

A separation of a heat sink from an electrical component can be achieved by providing an intermediate layer together with at least one layer of a thermal filler between the heat sink and the electrical component.

The intermediate layer may be at least one of the following:
a gauze;
a fiberglass structure;
a ceramic structure;
a foil;
a meshed structure;
a texture;
a textile.

As an option, the intermediate layer could be preprocessed with a primer to improve a contact with the thermal filler.

The intermediate layer may comprise a porosity, in particular holes in a more or less regular pattern. The holes may be symmetrically or asymmetrically distributed across the intermediate layer. The holes may be of substantially the same size and/or form or of different sizes and/or form.

A thermal filler is applied to either the heat sink or to the electrical component or to both. The intermediate layer can be provided on the heat sink to which the thermal filler has been applied (i.e. on top of the thermal filler) or it can be provided on the electrical component to which the thermal filler has been applied (i.e. on top of the thermal filler).

The process of attaching a heat sink on an electrical component may thus comprise the steps:
the thermal filler is applied on the electrical component;
the intermediate layer is provided on top of the thermal filler or on the heat sink;
the heat sink is put on top of the intermediate layer, wherein due to its porosity, a portion of the thermal filler penetrates the holes of the intermediate layer and provides thermal conductivity as well as adhesion between the intermediate layer and the heat sink; thus, the heat sink and the electrical component are thermally (and at least partially mechanically due to the adhesion of the thermal filler) coupled.

As an alternative, the process of attaching the heat sink to the electrical component may comprise the steps:
the thermal filler is applied on the heat sink;
the intermediate layer is provided on top of the thermal filler or on the component;
the electrical component is put on top of the intermediate layer, wherein due to its porosity, a portion of the thermal filler penetrates the holes of the intermediate layer and provides thermal conductivity as well as adhesion between the intermediate layer and the electrical component; thus, the heat sink and the electrical component are thermally (and at least partially mechanically due to the adhesion of the thermal filler) coupled.

In both scenarios, the heat sink may be pressed on the electrical component, either temporarily or (semi-)permanently. Hence, due to this mechanical impact, the thermal filler can penetrate the intermediate layer and provide thermal conductivity. The (semi-)permanent pressure could be achieved by a housing, which when closed, provides a protrusion that presses (e.g., via the thermal filler) against the intermediate layer. In such case, the protrusion can be part of the housing and in particular be (part of) the heat sink. For example, a metallic housing can provide a heat sink, which could be a common heat sink for several components on a (printed circuit) board.

According to another alternative, the process of attaching the heat sink to the electrical component may comprise the steps:
the thermal filler is applied on the heat sink and on the electrical component;
the intermediate layer is provided between the heat sink and the electrical component;
the intermediate layer provides thermal conductivity between the heat sink and the electrical component.

It is noted that the thermal filler may be applied on the heat sink and/or the electrical component and/or the intermediate layer (on one side or on both sides). Furthermore, the thermal filler may be applied in a certain pattern (comprising, e.g., dots or bars) and/or to a portion (e.g., 70% of the area or around the edges) of the heat sink, the electrical component and/or the intermediate layer.

It is further noted that the electrical component may be part of a printed circuit board. The electrical component may be a component that is susceptible to heat and requires cooling which is provided by said heat sink. In this regard, the electrical component may be an integrated circuit, e.g., a microcontroller, processor, memory device, ASIC, FPGA, transistor, or the like. It may be any electrical component exposed to high currents, which requires cooling, e.g., a power controller or any high current-carrying component.

The heat sink could be a cooling element of various shapes. It could be thermally coupled to a housing or even be part of the housing. The cooling element may comprise an active cooling (e.g., via a fan) or a passive cooling (e.g., via large cooling plates) means.

The thermal filler may be at least one of the following:
a thermal conductive gel;
a thermal conductive paste;
a thermal conductive liquid.

Advantageously, due to the intermediate layer, the mechanical stress to the electrical component (and/or to a circuit board to which the electrical component is attached) is significantly reduced when the heat sink is separated from the electrical component. Hence a disassembly can be conducted without damaging the electrical component, the circuit board or other components attached to the circuit board.

The intermediate layer could be larger than the component and, when being provided on top of the component, it could thereby avoid that the surrounding area of the component (e.g., other components and/or the PCB itself) is coated by the thermal filler. This bears the advantage that after being separated from the heat sink, the remainder of the thermal filler does not have to be removed from other components or from the PCB and thus significantly reduces the cleaning efforts (only the component to which the heat sink was attached is to be cleaned).

FIG. 1 shows a schematic comprising an electrical component 104 that is mounted on a printed circuit board (PCB) 105. A thermal filler 103 is applied on top of the electrical component 104 and an intermediate layer 102, e.g., a material comprising glass fiber with a given porosity, is arranged on top of the thermal filler 103. A heat sink 101 is mounted (e.g., pressed for a predetermined period of time with a predetermined amount of force) on this intermediate layer 102. Hence, the thermal filler 103 (at least partially) penetrates the intermediate layer 102 and provides a thermal conductivity between the electrical component 104 and the heat sink 101.

The heat sink 101 can be separated from the electrical component 104 by force, wherein the intermediate layer 102 facilitates such separation: The force required for separating the heat sink 101 from the electrical component 104 thus is significantly lower than in a scenario without such intermediate layer 102. In other words, the intermediate layer 102 reduces the area where the thermal filler 103 (viscoelastic material) connects the heat sink 101 with the electrical component 104. This reduces the adhesion provided by such thermal filler 103 and allows applying less force for separating the heat sink 101 from the electrical component 104 (compared to the scenario without such intermediate layer 102).

FIG. 2 shows a schematic based on FIG. 1, wherein the thermal filler 103 in this example is applied on the heat sink 101 and the intermediate layer 102 is arranged on the thermal filler 103. Then, the intermediated layer 102 can be pressed (for a given period of time with a given force) against the electrical component 104. The thermal filler 103 penetrates the (holes of the) intermediate layer 102 and provides a thermal connection (and adhesion) to the electrical component 104.

The heat sink 101 can be part of a housing in which the printed circuit board 105 is arranged. The housing may in this regard be a cooling element comprising active and/or passive cooling means. The housing could at least partially be a metal housing with cooling plates that dissipate heat from at least one electrical component 104.

FIG. 3 shows a schematic with a heat sink 301 that is thermally coupled with an electrical component 304 that is mounted on a PCB 305. Such thermal coupling is provided by an intermediate layer 302 connected
via a thermal filler 303 with the heat sink 301 and
via a thermal filler 306 with the electrical component 304.

The thermal fillers 303, 306 can be applied in various order, e.g., the thermal filler 306 could be applied on the electrical component 304 and/or on the intermediate layer 302. Accordingly, the thermal filler 303 could be applied on the heat sink 301 and/or on the intermediate layer 302.

The heat sink 301 is pressed against the electrical component 304 for a predefined period of time (with a given force). Then, the thermal connection between the heat sink 301 and the electrical component 304 via the thermal fillers 303, 306 and the intermediate layer 302 is established.

FIG. 4A shows an exemplary structure of an intermediate layer 102 or 302 comprising a meshed structure with a given porosity. A thermal filler can penetrate (e.g., via a force applied as described above) the holes of the meshed structure. The intermediate layer may be a gauze, a glass fiber, a foil, a meshed structure, a texture or a textile in particular with a given porosity.

FIG. 4B shows an alternative exemplary structure of an intermediate layer 102 or 302 comprising various holes of different form and diameter. The holes may be arranged in a regular or irregular pattern, they may be symmetrically arranged or all be of the same form and/or size. Also form and size may differ as indicated in FIG. 4B.

FIG. 5 shows a schematic based on FIG. 1, wherein a thermal filler 503 in this example is applied on a heat sink 501 and an intermediate layer 502 is arranged on the thermal filler 503. Then, the intermediated layer 502 can be pressed (for a given period of time with a given force) against the electrical component 504, which can be mounted (soldered or plugged into a socket) on a PCB 505. The thermal filler 503 penetrates the (holes of the) intermediate layer 502 and provides a thermal connection (and adhesion) to the electrical component 504. In the example of FIG. 5, the thermal filler 503 is applied to an area that is larger than the surface of the electrical component 504, but the thermal filler 503 does not reach the PCB 505, because the intermediate layer 502 is larger (in size and/or diameter) than the area coated by the thermal filler 503 as well as larger than the area of the electrical component 504. Hence, the thermal filler 503 can be efficiently kept from reaching the PCB 505, which significantly reduces cleaning efforts after the heat sink 501 is separated from the component 504.

FIG. 6 shows a housing 601, which is used as a heat sink comprising several protrusions 603, 604, 605, wherein each protrusion 603, 604, 605 is thermally coupled via a thermal filler 606, 607, 608 and an intermediate layer 602, 609, 610 to an electrical component 611, 612, 613, which is attached to (directly or via a socket) a PCB 614.

### LIST OF REFERENCES

101 heat sink
102 intermediate layer
103 thermal filler
104 electrical component
105 printed circuit board
301 heat sink
302 intermediate layer
303 thermal filler
304 electrical component
305 printed circuit board
306 thermal filler
501 heat sink
502 intermediate layer
503 thermal filler
504 electrical component
505 printed circuit board
601 housing/heat sink
602 intermediate layer
603 protrusion
604 protrusion
605 protrusion
606 thermal filler
607 thermal filler
608 thermal filler
609 intermediate layer
610 intermediate layer
611 electrical component
612 electrical component
613 electrical component
614 printed circuit board

1-15. (canceled)

16. A method of thermally coupling a heat sink to a component, the method which comprises:
applying a thermal filler and an intermediate layer between the heat sink and the component;
wherein the intermediate layer is formed with apertures; and
pressing the heat sink against the component with a given force in order for the thermal filler to penetrate the apertures of the intermediate layer.

17. The method according to claim 16, wherein said intermediate layer is formed with apertures of a uniform size and or shape.

18. The method according to claim 16, wherein said intermediate layer is formed with apertures of a different sizes and/or shapes.

19. The method according to claim 16, wherein the component is an electrical component.

20. The method according to claim 16, wherein the component is an integrated circuit mounted on a printed circuit board.

21. The method according to claim 16, wherein the heat sink is part of a housing or is thermally coupled with at least a portion of the housing.

22. The method according to claim 16, wherein the intermediate layer comprises at least one of the following:
a gauze;
a fiberglass structure;
a ceramic structure;
a foil;
a meshed structure;
a texture;
a textile.

23. The method according to claim 16, which comprises pre-processing the intermediate layer with a primer.

24. The method according to claim 16, wherein the intermediate layer is a porous layer.

25. The method according to claim 16, which comprises applying the thermal filler on the heat sink.

26. The method according to claim 16, which comprises applying the thermal filler on the component.

27. The method according to claim 16, which comprises applying the thermal filler on at least one side of the intermediate layer.

28. The method according to claim 16, wherein the thermal filler comprises at least one of the following:
a thermal conductive gel;
a thermal conductive paste;
a thermal conductive liquid.

29. A device, comprising:
a heat sink;
a component;
an intermediate layer and at least one thermal filler connecting said heat sink and said component with one another;
said intermediate layer having apertures formed therein; and
said thermal filler penetrating said apertures of said intermediate layer.

30. The device according to claim 29, wherein said heat sink is part of a housing.

31. The device according to claim 29, wherein said thermal filler is arranged on both sides of said intermediate layer.

32. The device according to claim 29, wherein said intermediate layer is larger than said component or said intermediate layer extends beyond an edge of said component.

33. The device according to claim 29, wherein said intermediate layer is formed with apertures of a uniform size and shape.

34. The device according to claim 29, wherein said intermediate layer is formed with apertures of different sizes and/or forms.

35. The device according to claim 29, wherein said component is an electrical component.

36. The device according to claim 35, wherein said component is an integrated circuit mounted on a printed circuit board.

37. The device according to claim 29, wherein said intermediate layer comprises at least one of the following:
a gauze;
a fiberglass structure;
a ceramic structure;
a foil;
a meshed structure;
a texture;
a textile.
